(19) United States
(12) Patent Application Publication
(10) Pub. No.: US 2014/0299870 A1
(43) Pub. Date: Oct. 9, 2014

(54) ORGANIC TRANSISTOR AND METHOD FOR MANUFACTURING SAME

(71) Applicant: Tokyo Electron Limited, Tokyo (JP)

(72) Inventors: Takashi Fuse, Yamanashi (JP); Misako Saito, Yamanashi (JP); Hiroshi Sato, Tokyo (JP)

(21) Appl. No.: 14/358,694

(22) PCT Filed: Nov. 14, 2012
(86) PCT No.: PCT/JP2012/079454

§ 371 Date: May 15, 2014

(30) Foreign Application Priority Data
Dec. 8, 2011 (JP) 2011-268827

(51) Int. Cl. H01L 51/05; H01L 51/00

(52) U.S. Cl. CPC H01L 51/0558; H01L 51/0002
USPC 257/40; 438/99

(57) ABSTRACT

A method for manufacturing an organic transistor includes laminating a base insulating layer on a substrate; forming source/drain electrodes on the base insulating layer; laminating an organic semiconductor layer to cover the electrodes and be in contact with the base insulating layer; laminating a gate insulating layer on the organic semiconductor layer; forming a gate electrode on the gate insulating layer; and performing, before the organic semiconductor layer is formed, surface treatment on the surface of the base insulating layer which is in contact with the organic semiconductor layer. The surface treatment is performed such that, when W1 represents the work of adhesion between two laminated layers using the same material of the organic semiconductor layer, the work of adhesion W2 between the base insulating layer and the organic semiconductor layer when the organic semiconductor layer is formed on the surface-treated base insulating layer satisfies the relationship W1≧W2.

### FIELD OF THE INVENTION

The present invention relates to an organic transistor and a method for manufacturing the same.

### BACKGROUND OF THE INVENTION

An organic transistor is a transistor using an organic semiconductor material. Currently, the organic transistor has a field effect mobility (hereinafter, simply referred to as “mobility”) of about 1 cm²/Vsec which is equal to that of amorphous silicon. The organic transistor is mainly classified into a top gate type structure and a bottom gate type structure in accordance with arrangement of a gate electrode. In the case of the top gate type structure, a channel is formed by laminating a gate insulating layer on an organic semiconductor layer. It is considered that the organic semiconductor layer is preferably made of a crystallized organic semiconductor material due to a high mobility.

Currently, the organic semiconductor layer is formed by deposition or coating. In that case, however, the organic semiconductor material becomes poly-crystalline. The mobility of the organic transistor having the poly-crystalline organic semiconductor layer is rate-limited by a boundary mobility between grains. A mobility μ and a grain size L of the organic semiconductor layer have the relationship of the following equation. The following equation shows that the mobility μ can be increased by increasing the grain size L of the organic semiconductor layer.

$$μ = \frac{q < v > L}{8 kT} exp [ - \frac{{E}_{b}}{kT} ] \qquad ( Eq . 1 )$$

(In this equation, <v> indicates an electron average speed, k indicates a Boltzman constant, and Eb indicates an activation energy.)

As for a technique for improving mobility of an organic transistor, there is proposed in Patent Document 1 (International Publication No. WO2008/117579) an organic transistor in which a first organic thin film such as pentacene or the like, and a second organic thin film such as tetraaryldiamine or the like or an inorganic insulating thin film such as Al2O3 or the like are alternately laminated on an insulating base.

Patent Document 2 (Japanese Patent Application Publication No. 2010-245114) discloses a technique for improving mobility by processing a gate insulating film with a coupling agent in an organic transistor having a bottom gate type structure. In Patent Document 2, a surface free energy is decreased by processing the gate insulating film with the coupling agent, so that the organic semiconductor layer having a large grain size can be obtained. Since the grain size becomes large, the boundary between grains which causes carrier trap is reduced, which results in the improvement of the mobility.

Patent Document 3 (Japanese Patent Application Publication No. 2010-141142) suggests a technique for forming a coating thin film having a surface free energy of 50 mJ/m² or less on a gate insulating film in an organic transistor having a bottom gate type structure. Accordingly, it is disclosed in Patent Document 3 that when a semiconductor active layer such as pentacene or the like is made to grow on the thin film, the semiconductor active layer having less defects which are causes of a carrier trap can grow.

Patent Document 4 (International Publication No. WO2006/137233) relates to a method for forming an organic semiconductor material thin film by coating liquid containing an organic semiconductor material on a substrate surface. In Patent Document 4, on the assumption that a surface free energy of the substrate surface is expressed by γₛ=γₛ^{d}+γₛ^{p}+γₛ^{h} and a surface free energy of solvent in the liquid is expressed by γ_{L}=γ_{L}^{d}+γ_{L}^{p}+γ_{L}^{h}(γₛ^{d}, γₛ^{p}, γₛ^{h} represent a non-polar component, a polar component, and a hydrogen bond component of the surface free energy of the solid based on Young-Fowkes equation, respectively; and γ_{L}^{d}, γ_{L}^{p}, γ_{L}^{h}, represent a non-polar component, a polar component, and a hydrogen bond component of the surface free energy of the liquid based on Young-Fowkes equation, respectively), it is suggested to set the value of γₛ^{h}−γ_{L}^{h} to be greater than or equal to −5 mN/m and smaller than or equal to 20 mN/m. Accordingly, it is described in Patent Document 4 that a high-performance organic thin film transistor having an improved mobility can be manufactured. As for a method for controlling the surface free energy, there may be employed treatment for changing surface roughness of the surface substrate, treatment using a silane coupling agent, orientation treatment such as rubbing, or the like.

As described above, the surface treatment or the interposition of the thin film is suggested to improve the mobility of the organic transistor. However, the proposals of Patent Documents 1 to 3 are designed for the organic transistor having a bottom gate type structure and thus are not suitable for the improvement of the mobility of the organic transistor having a top gate type structure in which a channel is formed by laminating a gate insulating layer on an organic semiconductor layer. Although Patent Document 4 discloses the application to the organic transistor having a top gate structure, a surface treatment target in that case is a glass substrate or a supporting body (substrate) such as a plastic film or the like, and a specific technique for the surface treatment is not described.

### SUMMARY OF THE INVENTION

The present invention provides a high-mobility organic transistor having a top gate structure.

In view of the above, the present inventors have conceived the present invention by conducting research and discovering that a high-mobility organic transistor can be manufactured by performing surface treatment which satisfies the relationship W1≧W2 in advance on a first insulating layer as a base of an organic semiconductor layer in the organic transistor having a top gate structure. Here, W1 indicates the work of bonding a organic semiconductor layer on another organic semiconductor layer, and W2 indicates the work of bonding a organic semiconductor layer on the first insulating layer as the surface-treated base.

In accordance with a first aspect of the present invention, there is provided an organic transistor including: a supporting body; a first insulating layer laminated on the supporting body; an organic semiconductor layer laminated on the first insulating layer; a pair of source/drain electrodes partially in contact with the organic semiconductor layer; a second insulating layer laminated on the organic semiconductor layer; and a gate electrode formed on the second insulating layer, wherein a surface of the first insulating layer which is in contact with the organic semiconductor layer has been subjected to a surface treatment by which, when W1 represents a work of adhesion between two laminated layers using the same material as a material of the organic semiconductor layer, a work of adhesion W2 between the first insulating layer and the organic semiconductor layer in the case of forming the organic semiconductor layer on the surface-treated first insulating layer satisfies relationship W1≧W2.

At least a part of the surface of the first insulating layer, which corresponds to a channel area formed in the boundary between the organic semiconductor layer and the second insulating layer, may have been subjected to the surface treatment.

The surface treatment may be a treatment for adhering a saturated hydrocarbon compound with 10 to 30 carbon atoms on the surface of the first insulating layer.

The material of the organic semiconductor layer may be pentacene.

A material of the first insulating layer may be SrTiO₃.

The pair of source/drain electrodes may have a top gate/bottom contact type structure provided below the organic semiconductor layer. In this case, a self-assembled monolayer film may be formed on the pair of source/drain electrodes.

In accordance with a second aspect of the present invention, there is provided a method for manufacturing an organic transistor including a supporting body, a first insulating layer laminated on the supporting body, an organic semiconductor layer laminated on the first insulating layer, a pair of source/drain electrodes partially in contact with the organic semiconductor layer, a second insulating layer laminated on the organic semiconductor layer, and a gate electrode formed on the second insulating layer, the method including: performing surface treatment on a surface of the first insulating layer which is to come in contact with the organic semiconductor layer; and forming the organic semiconductor layer on the first insulating layer after the surface treatment, wherein the surface treatment is performed such that, when W1 represents a work of adhesion between two laminated layers using the same material as a material used in the organic semiconductor layer, a work of adhesion W2 between the first insulating layer and the organic semiconductor layer in the case of forming the organic semiconductor layer on the surface-treated first insulating layer satisfies relationship W1≧W2.

### Effect of the Invention

As described above, the work of bonding the first insulating layer and the organic semiconductor layer is controlled to facilitate the crystal growth of molecules forming the organic semiconductor layer and further to increase a grain size. As a consequence, the regularity of crystal is improved, and the surface of the organic semiconductor layer can be planarized. As a result, it is possible to reduce a carrier mobility barrier in a channel area of the interface between the organic semiconductor layer and the second insulating layer and improve the mobility of the organic transistor.

### BRIEF DESCRIPTION OF THE DRAWINGS

FIG. 1 is a cross sectional view showing a schematic configuration of an organic transistor in accordance with a first embodiment of the present invention.

FIG. 2 is a graph showing relationship between a coverage ratio of a pentacene thin film on an amorphous SrTiO₃ thin film and a work of bonding.

FIGS. 3A to 3D schematically show processes of a method for manufacturing an organic transistor in accordance with the first embodiment.

FIGS. 4A to 4C schematically show processes continued from FIG. 3.

FIG. 5 schematically explains a modification of the first embodiment.

FIG. 6 schematically explains another modification of the first embodiment.

FIG. 7 is a cross sectional view schematically showing an organic transistor in accordance with a second embodiment of the present invention.

FIG. 8 explains a part of processes of a method for manufacturing an organic transistor in accordance with a third embodiment of the present invention.

### DETAILED DESCRIPTION OF THE EMBODIMENTS

Hereinafter, embodiments of the present invention will be described with reference to the accompanying drawings.

### First Embodiment

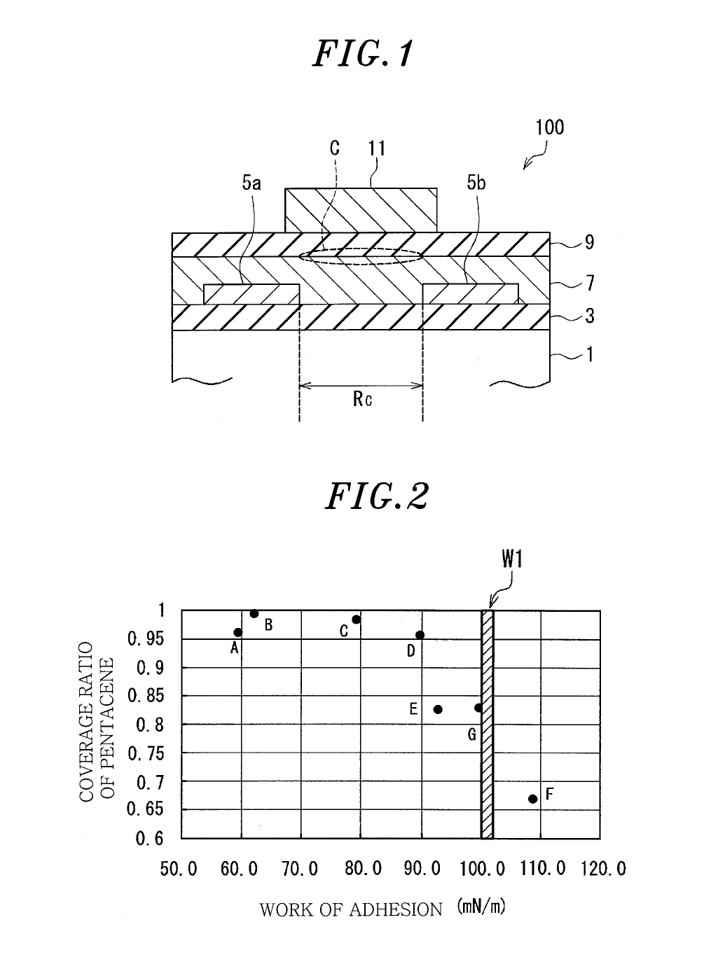

FIG. 1 is a cross sectional view showing a schematic configuration of an organic transistor 100 in accordance with a first embodiment of the present invention. The organic transistor 100 has a so-called top gate/bottom contact type structure. In other words, the organic transistor 100 includes: a substrate 1 that is a supporting body; a base insulating layer 3 that is a first insulating film formed on the substrate 1 with a predetermined thickness; a pair of source/drain electrodes 5a and 5b formed in a predetermined pattern on a part of the base insulating layer 3; an organic semiconductor layer 7 laminated so as to cover the source/drain electrodes 5a and 5b and be in contact with the base insulating layer 3; a gate insulating layer 9 as a second insulating layer laminated on the organic semiconductor layer 7; and a gate electrode 11 laminated on the gate insulating layer 9. The surface treatment is performed on the surface of the base insulating layer 3 which is in contact with the organic semiconductor layer 7, and with respect to the work of adhesion W1 in the case where the organic semiconductor layer 7 is formed on another organic semiconductor layer, the work of adhesion W2 between the base insulating layer 3 and the organic semiconductor layer 7 in the case of forming the organic semiconductor layer 7 on the surface-treated base insulating layer 3 satisfies the relationship W1≧W2.

<Substrate>

The substrate 1 may be made of an inorganic material or an organic material generally used for an organic transistor, e.g., glass, quartz, monocrystalline silicon, polycrystalline silicon, amorphous silicon, synthetic resin or the like. Here, the synthetic resin may include, e.g., polyethyleneterephthalate, polyethylenenaphthalate, polyethersulfone, polyetherimide, polyetheretherketone, polyphenylenesulfide, polyarylate, polyimide, polycarbonate or the like. As for the substrate 1, a composite substrate made of combination of the above materials may be used. Moreover, the substrate 1 may have a multilayer structure.

<Base Insulating Layer>

As for an insulating material forming the base insulating layer 3, an inorganic insulating material or an organic insulating material generally used for the organic transistor may be used.

The inorganic insulating material includes a metal oxide, e.g., aluminum oxide, tantalum oxide, titanium oxide, tin oxide, vanadium oxide, strontium titanate, barium strontium titanate, barium titanate zirconate, lead titanate zirconate, lanthanum lead titanate, barium titanate, barium fluoride magnesium, bismuth titanate, bismuth strontium titanate, bismuth strontium tantalate, bismuth niobate tantalate, yttrium trioxide, hafnium hydroxide or the like, in addition to glass, silicon oxide (SiO₂), silicon nitride, aluminum nitride or the like. Among these, it is preferable to use a metal oxide such as strontium titanate or the like which has a comparatively high relative dielectric constant, an amorphous structure, and a high dielectric withstanding voltage.

As for the organic insulating material, it is possible to use a polymer material, e.g., polyimide, polyamide, polyester, polyacrylate, phenol-based resin, fluorine-based resin, epoxy-based resin, novolac-based resin, vinyl-based resin or the like.

Although a single base insulating layer 3 is shown in FIG. 1, the base insulating layer 3 may be formed by laminating a plurality of insulating films.

<Source/Drain Electrode>

As for the material (electrode material) of the source/drain electrodes 5a and 5b, it is possible to use a conductive material that is generally used for the organic transistor. The conductive material may be a metal material, e.g., Ag, Au, Ta, Ti, Al, Zr, Cr, Nb, Hf, Mo, alloy of those metals, indium-tin-oxide alloy (ITO), indium-zinc-oxide (IZO) or the like, a silicon-based material such as monocrystalline silicon, polycrystalline silicon, amorphous silicon or the like, a carbon material such as carbon black, graphite or the like, or a conductive polymer material.

<Organic Semiconductor Layer>

The organic semiconductor material forming the organic semiconductor layer 7 may be a material that can form the organic semiconductor layer 7 having desired semiconductor characteristics, e.g., an aromatic compound, a chain compound, an organic pigment, an organosilicon compound or the like. More specifically, it may be, e.g., a low molecular organic compound such as pentacene or the like, a high molecular organic compound such as polypyrrole, polythiophene, polyisothianaphthene, polytenylenevinylene, poly(p-phenylenevinylene), polyaniline, polyacetylene, polyazulene or the like. Among these, it is preferable to use a polycyclic aromatic compound such as pentacene or the like which can improve the mobility of the organic transistor 100 and simply control a film thickness. An acene-based polycyclic aromatic compound such as pentacene has a large number of benzene rings. Thus, superposition between molecules is increased by the expansion of it electron system, and the improvement of the mobility can be expected.

The thickness of the organic semiconductor layer 7 may be properly set in accordance with types of organic semiconductor materials or the like. For example, it may be set within a range from about 1.5 nm to 15 nm.

<Gate Insulating Layer>

As for the insulating material forming the gate insulating layer 9, it is possible to use an inorganic insulating material or an organic insulating material which is generally used for the organic transistor.

The inorganic insulating material may be, e.g., glass, silicon oxide (SiO₂), silicon nitride, aluminum nitride or the like. In addition, the inorganic insulating material may be a metal oxide such as aluminum oxide, tantalum oxide, titanium oxide, tin oxide, vanadium oxide, strontium titanate, barium strontium titanate, barium titanate zirconate, lead titanate zirconate, lanthanum lead titanate, barium titanate, barium fluoride magnesium, bismuth titanate, bismuth strontium titanate, bismuth strontium tantalate, bismuth niobate tantalate, yttrium trioxide, hafnium hydroxide or the like. Among these, it is preferable to use a metal oxide such as strontium titanate which has a high dielectric withstanding voltage, an amorphous structure and a comparatively high relative dielectric constant even in a thin film state.

As for the organic insulating material, it is possible to use a polymer material, e.g., polyimide, polyamide, polyester, polyacrylate, phenol-based resin, fluorine-based resin, epoxy-based resin, novolac-based resin, vinyl-based resin or the like.

The thickness of the gate insulating layer 9 may be properly set in accordance with types of insulating materials. For example, it may be set within a range from about 50 nm to 1000 nm and preferably within a range from about 100 nm to 300 nm.

<Gate Electrode>

As for the material forming the gate electrode 11, it is possible to use a conductive material generally used for the organic transistor. The conductive material may be a metal material, e.g., Ag, Au, Ta, Ti, Al, Zr, Cr, Nb, Hf, Mo, alloy of those metals, indium-tin-oxide alloy (ITO), indium-zinc-oxide (IZO) or the like, a silicon-based material such as monocrystalline silicon, polycrystalline silicon, amorphous silicon or the like, a carbon material such as carbon black, graphite or the like, or a conductive polymer material.

<Surface Treatment>

The surface treatment is performed on the surface of the base insulating layer 3 which is in contact with the organic semiconductor layer 7. If W1 represents the work of adhesion between the organic semiconductor layers 7, the work W2 of adhesion between the base insulating layer 3 and the organic semiconductor layer 7 in the case of forming the organic semiconductor layer 7 on the surface-treated base insulating layer 3 satisfies the relationship W1≧W2.

Here, as will be shown in the following equation, the work of bonding indicates a difference between the sum of the surface free energy of the liquid and the surface free energy of the solid and the interface free energy of the liquid and the solid after the adhesion.

W_{SL}=(γₛ+γ_{L})−γ_{SL} (1)

(Here, W_{SL} indicates the work of adhesion; γₛ indicates the surface free energy of the solid; γ_{L} indicates the surface free energy of the liquid; and γ_{SL} indicates the interface free energy of the solid and the liquid after the adhesion.)

FIG. 2 shows a measurement result of a coverage ratio in the case of forming a pentacene thin film that is an organic semiconductor material on an amorphous-strontium titanate (a-SrTiO₃) thin film that is an inorganic insulating material under the condition in which the work W2 of adhesion has been changed by changing the surface state of the a-SrTiO₃ thin film. The a-SrTiO₃ thin film was formed with a thickness of 100 nm at the room temperature by a plasma sputter deposition. Further, the pentacene thin film was formed with a thickness of 2 nm by vacuum deposition while setting a substrate temperature to the room temperature. Here, the work of adhesion W1 in the case where the pentacene thin film is formed on the pentacene thin film is about 100 mN/m (indicated by a shaded portion in FIG. 2).

In FIG. 2, the case where the surface of the a-SrTiO₃ was not treated (notation A), the case where the surface of the a-SrTiO₃ was subjected to C₂₀H₄₄ treatment (notation B) as surface treatment, the case where the surface of the a-SrTiO₃ was subjected to CxFy treatment (notation C; x and y being stoichiometric values, the same being true in the following) as surface treatment, the case where the surface of the a-SrTiO₃ was subjected to UV treatment (notation D) as surface treatment, the case where the surface of the a-SrTiO₃ was subjected to combined treatment of UV treatment and annealing treatment at 230° C. (notation E) as surface treatment, the case where the surface of the a-SrTiO₃ was subjected to radical treatment (notation F) as surface treatment, and the case where the surface of the a-SrTiO₃ was subjected to dibutyl phthalate treatment (notation G) as surface treatment are plotted as values of the work of adhesion between the a-SrTiO₃ and the pentacene.

Each of the surface treatments was performed under the following conditions. The C₂₀H₄₄ treatment was performed by sealing solid C₂₀H₄₄ and an a-SrTiO₃ substrate in a schale. The CxFy treatment was performed by sealing a vacuum grease such as Fomblin (Registered Trademark; Solvay Specialty Polymers, Inc.) and an a-SrTiO₃ substrate in a schale. The UV treatment was performed by exposing an a-SrTiO₃ substrate to UV light in the atmosphere for 10 minutes by the UV treatment apparatus using UV light with a wavelength of 185 nm. In the case of the combined treatment of the UV treatment and the annealing treatment, the UV treatment was performed under the conditions described above and, then, the annealing was performed in the vacuum state. The radical treatment was performed by an O₂ plasma asking apparatus. The dibutyl phthanate treatment was performed by sealing dibutyl phthalate solution and an a-SrTiO₃ substrate in a schale.

The UV treatment (notation D), the UV treatment and the annealing treatment at 230° C. (notation E), and the radical treatment (notation F) are surface treatments for cleaning the a-SrTiO₃ surface. As will be described later, in the non-treatment (notation A) state, an organic material may be attached to the a-SrTiO₃ surface. The organic material, however, are removed from the a-SrTiO₃ surface by the above treatment. Therefore, a substantially clean state is obtained and the work of adhesion W2 is increased compared to the case of the non-treatment (notation A). In the UV treatment (notation D) and the UV treatment and the annealing treatment at 230° C. (notation E), the organic materials remain due to insufficient cleaning. As a result, the work of adhesion W2 is within a tolerable range. However, the work of adhesion W2 is greater than the work of adhesion W1 due to the excessive cleaning performed by the radical treatment (notation F).

Meanwhile, in the C₂₀H₄₄ treatment (notation B) and the CxFy treatment (notation C), the molecules are attached by interaction to the a-SrTiO₃ surface with a thickness of a single molecular layer or less. As a consequence, the a-SrTiO₃ surface is inactivated, and the work of adhesion W2 is sufficiently decreased.

In the dibutyl phthanate treatment (notation G), since double bonds of oxygen atoms exist in the dibutyl phthanate chemical structure, the oxygen atoms react with moisture in the atmosphere after the surface treatment, and this slightly increases of the work of adhesion W2. However, the work of adhesion W2 is substantially equal to the work of adhesion W1, and the effect of the surface treatment is obtained.

In the case of non-treatment (notation A), an organic material may be attached to the a-SrTiO₃ surface, which is considered as a cause of a high coverage ratio and a low work of bonding. Therefore, in the case of non-treatment (notation A), the coverage ratio is excellent whereas it is difficult to recognize the type and the amount of the attached material, which is not preferable in managing the crystallinity or the coverage ratio of pentacene. However, the organic contamination functions to reduce the work of adhesion W2 between pentacene and the a-SrTiO₃ surface. As a result, the relationship W1≧W2 is satisfied, and a high coverage ratio is obtained.

The result of the test shown in FIG. 2 shows that when the base insulating layer 3 is an a-SrTiO₃ thin film, the C₂₀H₄₄ treatment (notation B) and the CxFy treatment (notation C) are preferable as the surface treatment because the effect of decreasing the work of adhesion W2 is excellent. Further, the surface treatment is performed such that, with respect to the work of adhesion W1 in the case where the organic semiconductor layer 7 (pentacene) is formed on the organic semiconductor layer (pentacene), the work of adhesion W2 between the base insulating layer 3 and the organic semiconductor layer 7 in the case of forming the organic semiconductor layer 7 on the surface-treated base insulating layer 3 satisfies the relationship W1≧W2. Such a surface treatment facilitates crystal growth of molecules forming the organic semiconductor layer 7, so that the grain size is increased and the regularity of crystal is improved. Accordingly, the surface of the organic semiconductor layer 7 can be planarized.

Although the mechanism for obtaining the above-described effects by setting the works of adhesion to satisfies W1≧W2 is not clear, such a mechanism can be explained by the following description on the balance between the interaction of the organic semiconductor layer 7 and the base insulating layer 3 and the cohesive property (easiness of crystallization) of the organic semiconductor material forming the organic semiconductor layer 7. The organic semiconductor material originally has a high cohesive property and is easily crystallized (i.e., easily self-assembled). In the case of forming the organic semiconductor layer 7 by, e.g., deposition, if the wettability between the organic semiconductor layer 7 and the base insulating layer 3 is large (W1<W2), the organic semiconductor layer 7 is wetted (bonded) to the base insulating layer 3 rather than being crystallized by itself. Thus, the organic semiconductor layer 7 may remain in that position, and the crystal growth starts in that position. As the crystal growth site is increased, the crystal orientation is decreased, which may result in decrease of the grain size. On the other hand, if the wettability between the organic semiconductor layer 7 and the base insulating layer 3 is small (W1≧W2), the molecules can freely move on the base insulating layer 3 without staying in a specific location. Accordingly, the crystals are formed while utilizing the cohesive property of molecules. As a result, a large grain is formed and the surface is planarized. Hence, the carrier mobility barrier in a channel area C on the interface between the organic semiconductor layer 7 and the gate insulating layer 9 is reduced, and the mobility of the organic transistor 100 can be improved.

(Method for Manufacturing an Organic Transistor)

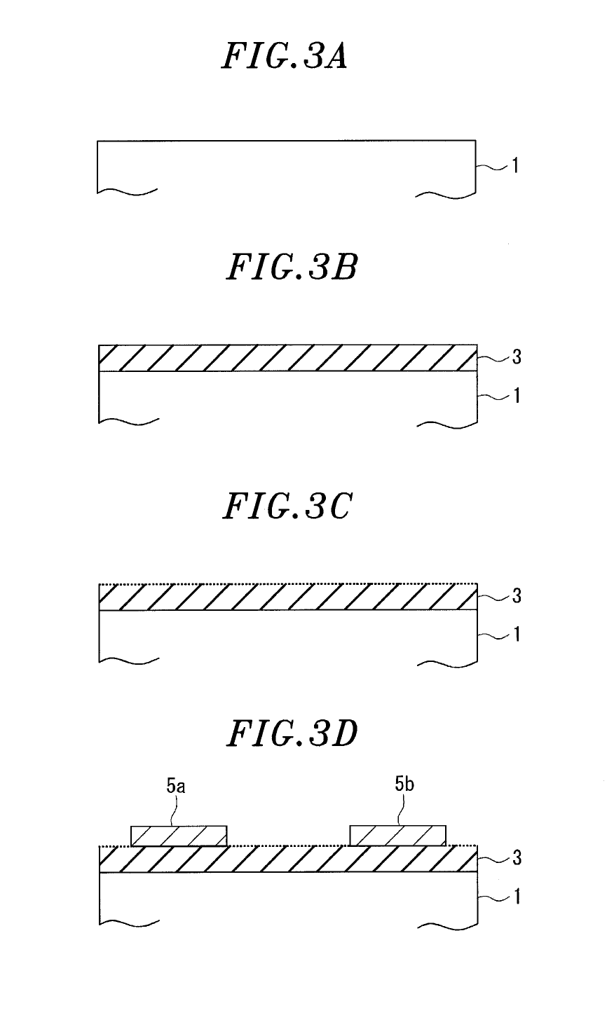

Hereinafter, a method for manufacturing an organic transistor 100 of the present embodiment will be described with reference to FIGS. 3A to 6. FIGS. 3A to 6 schematically show cross sectional structures of a substrate surface in order to explain processes of the method for manufacturing the organic transistor 100 of the present embodiment. The method for manufacturing the organic transistor 100 of the present embodiment at least includes: a step for laminating the base insulating layer 3 on the substrate 1; a step for forming the source/drain electrodes 5a and 5b on the base insulating layer 3; a step for laminating the organic semiconductor layer 7 to cover the source/drain electrodes 5a and 5b and be in contact with the base insulating layer 3; a step for laminating the gate insulating layer 9 on the organic semiconductor layer 7; and a step for forming the gate electrode 11 on the gate insulating layer 9. The method for manufacturing the organic transistor 100 of the present embodiment further includes, before the step for forming the organic semiconductor layer 7, a step for performing surface treatment on the surface of the base insulating layer 3 which is to come in contact with the organic semiconductor layer 7. The organic semiconductor layer 7 is formed on the surface-treated base insulating layer 3. Here, the surface treatment is performed such that, with respect to the work of adhesion W1 in the case where the organic semiconductor layer 7 is formed on the organic semiconductor layer and the work of adhesion W2 between the base insulating layer 3 and the organic semiconductor layer 7 in the case of forming the organic semiconductor layer 7 on the surface-treated base insulating layer 3 satisfies the relationship W1≧W2. Further, the method for manufacturing the organic transistor 100 of the present embodiment may include another step if necessary.

<Step for Forming Base Insulating Layer>

FIGS. 3A and 3B show the step of forming the base insulating layer 3. In this step, the base insulating layer 3 is laminated on the substrate 1. A method for forming the base insulating layer 3 is not particularly limited. When the base insulating layer 3 is made of an inorganic insulating material, the base insulating layer 3 may be formed by a dry process or a wet process. The dry process includes, e.g., a vacuum deposition method, a molecular beam epitaxial growth method, an ion cluster beam method, a low energy ion beam method, an ion coating method, a CVD method, a sputtering method, an atmospheric plasma method and the like. The wet process includes, e.g., a coating method such as a spin coating method, a die coating method, a role coating method, a bar coating method, an LB method, a dip coating method, a spray coating method, a blade coating method, a casting method or the like; an ink jet method, a screen printing method, a pad printing method, a flexo printing method, a micro contact printing method, a gravure printing method, an offset printing method, a gravure offset printing method or the like. When the base insulating layer 3 is made of an organic insulating material, it is preferable to form the base insulating layer 3 by the wet process.

In the present embodiment, the base insulating layer 3 is preferably formed by, e.g., the vacuum deposition method, the MOCVD method or the like, in view of ensuring uniformity of the film.

<Surface Treatment Step>

FIGS. 3B and 3C show the surface treatment step. The surface treatment step is performed such that, with respect to the work of adhesion W1 in the case where the organic semiconductor layer 7 is formed on the organic semiconductor layer, the work of adhesion W2 between the base insulating layer 3 and the organic semiconductor layer 7 in the case of forming the organic semiconductor layer 7 on the surface-treated base insulating layer 3 satisfies the relationship W1≧W2 by changing the surface state of the base insulating layer 3. In FIG. 3C, the state in which the entire surface of the base insulating layer 3 is surface-treated is indicated by a dashed line.

The surface treatment may be any one of the following treatments.

(i) treatment for inactivating the surface of the base insulating layer 3

(ii) treatment for reducing active species on the surface of the base insulating layer 3

(iii) treatment for removing moisture from the surface of the base insulating layer 3

The first treatment (i) includes treatment for adhering an inert material onto the surface of the base insulating layer 3. The inert material may be, e.g., saturated hydrocarbon (CxHy), a non-volatile organic material (e.g., CxFy used as a vacuum grease), Sr atom or the like. By adhering the inert material, active portions onto the surface of the base insulating layer 3 are terminated, and the wettability to the organic semiconductor material is improved. Accordingly, the grain boundary of the organic semiconductor material is decreased and the carrier scattering by the grain boundary is decreased. As a result, the improvement of the mobility can be expected. Here, as for the saturated hydrocarbon (CxHy), a saturated hydrocarbon compound having 10 to 30 carbon atoms, e.g., C₂₀H₄₄ or the like, is preferably used. For example, when the base insulating layer 3 is made of a-SrTiO₃, C₂₀H₄₄ is bonded by interaction to a non-bonded site where neither O atom nor Ti atom is bonded in the base insulating layer 3. Accordingly, the non-bonded site is terminated and the surface of the base insulating layer 3 is inactivated.

The step for inactivating the surface of the base insulating layer 3 can be performed by exposing the surface of the base insulating layer 3 to vapor of an inert material such as saturated hydrocarbon (CxHy) in an airtight container and adhering the inert material onto the surface of the base insulating layer 3, for example. In the case of using, e.g., saturated hydrocarbon (CxHy), it is preferable to perform the inactivation treatment by activating the surface of the base insulating layer 3 by treatment such as UV treatment, solution cleaning or the like, and then sealing the base insulating layer 3 in the CxHy atmosphere.

The second treatment (ii) includes treatment for supplying atoms or molecules reactive to the active species on the surface of the base insulating layer 3. The active species on the surface of the base insulating layer 3 may be, e.g., double bond of oxygen atoms, Ti atom or the like.

The third treatment (iii) may include treatment for removing moisture by annealing the surface of the base insulating layer 3 in the vacuum state.

<Step for Forming Source/Drain Electrode>

In the step for forming the source/drain electrode, the source/drain electrodes 5a and 5b are formed on the base insulating layer 3 at a predetermined interval corresponding to the channel area C, as shown in FIGS. 3C and 3D. A method for forming the source/drain electrodes 5a and 5b is not particularly limited. For example, the source/drain electrodes 5a and 5b may be formed by forming a conductive layer on the entire base insulating layer 3 and patterning the conductive layer by a photolithography technique and etching. Or, the source/drain electrodes 5a and 5b may be formed in a pattern directly on the base insulating layer 3 by a screen printing method, an ink jet method, a deposition method or the like.

<Step for Forming Organic Semiconductor Layer>

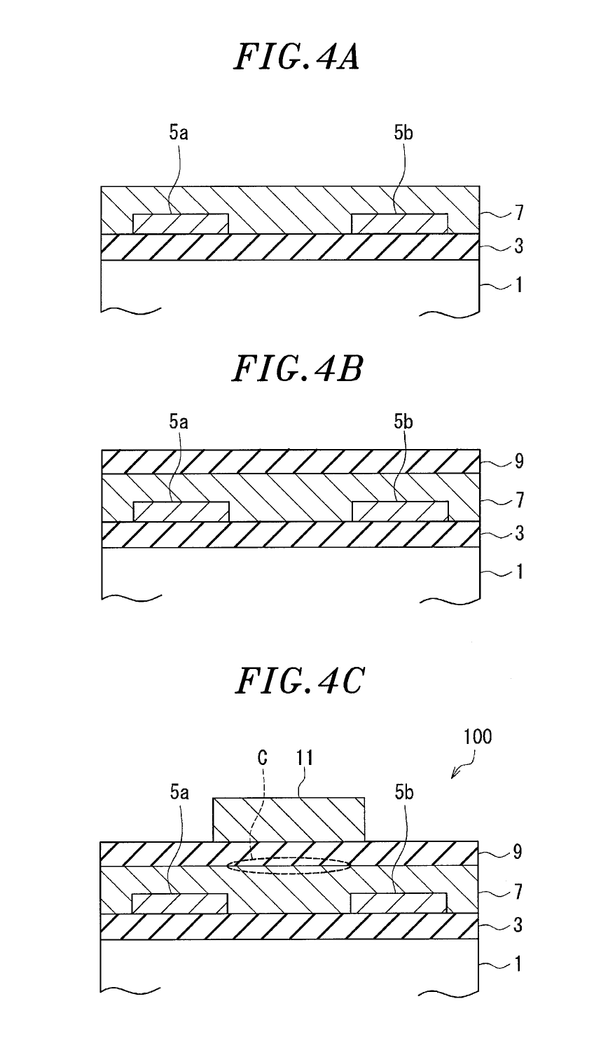

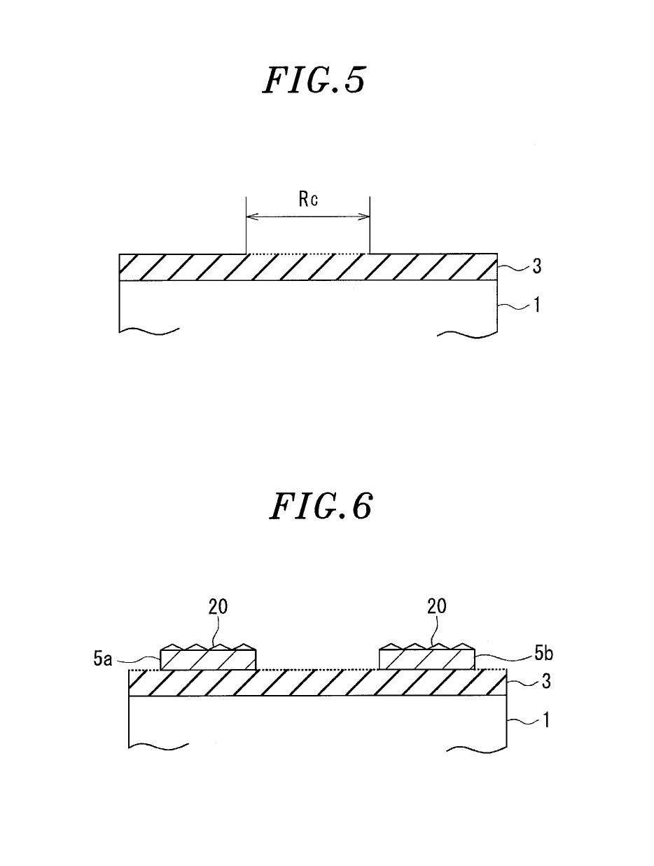

In the step for forming the organic semiconductor layer 7, the organic semiconductor layer 7 is laminated to cover the source/drain electrodes 5a and 5b and be in contact with the base insulating layer 3. Accordingly, the organic semiconductor layer 7 is formed, as shown in FIG. 4A. The organic semiconductor layer 7 may be formed by, e.g., a dry process or a wet process. The dry process may be, e.g., a vacuum deposition method, a molecular beam epitaxial growth method, an ion cluster beam method, a low energy ion beam method, an ion coating method, a CVD method, a sputtering method, an atmospheric plasma method or the like. The wet process may be, e.g., a coating method such as a spin coating method, a die coating method, a role coating method, a bar coating method, an LB method, a dip coating method, a spray coating method, a blade coating method, a casting method or the like, or an ink jet method, a screen printing method, a pad printing method, a flexo printing method, a micro contact printing method, a gravure printing method, an offset printing method, a gravure offset printing method or the like.

Since the channel area C is formed in the interface between the organic semiconductor layer 7 and the gate insulating layer 9, it is preferable to obtain a flat surface by minimizing the surface roughness Ra of the organic semiconductor layer 7 in order to improve the mobility of the organic transistor 100. In the present embodiment, with respect to the work of adhesion W1 in the case where the organic semiconductor layer 7 (e.g., pentacene) is formed on the organic semiconductor layer (e.g., pentacene), the work of adhesion W2 between the base insulating layer 3 and the organic semiconductor layer 7 in the case of forming the organic semiconductor layer 7 on the surface-treated base insulating layer 3 satisfies the relationship W1≧W2 by performing the surface treatment on the base insulating layer 3 below the organic semiconductor layer 7. Hence, the surface of the organic semiconductor layer 7 is planarized, and the surface roughness Ra of the organic semiconductor layer 7 can be reduced.

<Step for Forming Gate Insulating Layer>

In the step for forming the gate insulating layer 9, the gate insulating layer 9 is laminated on the organic semiconductor layer 7 as shown in FIGS. 4A and 4B. A method for forming the gate insulating layer 9 is not particularly limited. When the gate insulating layer 9 is made of an inorganic insulating material, the gate insulating layer 9 can be formed by a dry process or a wet process. The dry process may be, e.g., a vacuum deposition method, a molecular beam epitaxial growth method, an ion cluster beam method, a low energy ion beam method, an ion coating method, a CVD method, a sputtering method, an atmospheric plasma method or the like. The wet process may be a coating method such as a spin coating method, a die coating method, a role coating method, a bar coating method, an LB method, a dip coating method, a spray coating method, a blade coating method, a casting method or the like, or an ink jet method, a screen printing method, a pad printing method, a flexo printing method, a micro contact printing method, a gravure printing method, an offset printing method, a gravure offset printing method or the like. Further, when the gate insulating layer 9 is made of an organic insulating material, the gate insulating layer 9 is preferably formed by the wet process.

<Step for Forming Gate Electrode>

In the step for forming the gate electrode 11, the gate electrode 11 is formed on the gate insulating layer 9 as shown in FIGS. 4B and 4C. A method for forming the gate electrode 11 is not particularly limited and may be determined in accordance with the material of the gate electrode 11. The method for forming the gate electrode 11 in a pattern on the gate insulating layer 9 may include a method for forming the gate electrode 11 by coating a conductive layer on the entire surface of the gate insulating layer 9 and patterning the conductive layer by a photolithography technique, or a method for forming the gate electrode 11 in a pattern directly on the gate insulating layer 9 by a screen printing method, an ink jet method, a deposition method or the like.

Due to the above processes, the organic transistor 100 shown in FIG. 1 can be manufactured. The organic transistor 100 of the present embodiment, e.g., an organic field effect transistor such as a thin film transistor (TFT) or the like can be preferably used for a liquid display device, an organic EL display device, an electrophoretic display device or the like.

Hereinafter, a modification of the first embodiment will be described.

<First Modification>

In the surface treatment step, the surface treatment may be performed on the entire base insulating layer 3, as shown in FIG. 3C. Or, the surface treatment may be performed on a part of the base insulating layer 3. For example, the surface treatment may be performed on a part of the base insulating layer 3 which includes an area (channel corresponding area Rc) on the base insulating layer 3 corresponding to the channel area C formed on the boundary between the organic semiconductor layer 7 and the gate insulating layer 9, as shown in FIG. 5.

<Second Modification>

After the source/drain electrodes 5a and 5b are formed as shown in FIG. 3D, a self-assembled monolayer (SAM) film 20 may be formed on the source/drain electrodes 5a and 5b as shown in FIG. 6. By forming the SAM film 20, the surface free energies of the surfaces of the source/drain electrodes 5a and 5b are decreased and the wettability of the organic semiconductor material is improved. This leads to the improvement of the crystallinity (size or arrangement of crystals) of the organic semiconductor material and the improvement of the electrical connection between the source/drain electrodes 5a and 5b and the organic semiconductor layer 7.

Although it is not illustrated, the SAM film 20 has a structure in which a plurality of compound molecules that are monomolecular in thickness is arranged in a width direction. Each compound molecule has at one end a coupler coupled to the source/drain electrodes 5a and 5b and at the other end a water repellent end group. Here, the coupler coupled to the source/drain electrodes 5a and 5b may be selected in accordance with materials of the source/drain electrodes 5a and 5b. For example, when the source/drain electrodes 5a and 5b are made of metal such as Au, Ag, Cu or the like, a thiol (SH) group or a disulphide (SS) group is preferably used as the coupler. As for the water repellent end group, a methyl group (CH₃), fluorine (F) or the like is preferably used. Specifically, when the source/drain electrodes 5a and 5b are made of Au, alkanethiol or the like may be used for the SAM film 20.

As described above, in the organic transistor 100 of the present embodiment, the surface treatment is performed in advance on the base insulating layer 3 formed on the substrate 1. Due to the surface treatment, with respect to the work of adhesion W1 in the case where the organic semiconductor layer 7 is formed on the organic semiconductor layer, and the work of adhesion W2 between the base insulating layer 3 and the organic semiconductor layer 7 in the case of forming the organic semiconductor layer 7 on the surface-treated insulating layer 3 satisfies the relationship W1≧W2. The work of bonding the base insulating layer 3 and the organic semiconductor layer 7 is controlled to facilitate the crystal growth of molecules forming the organic semiconductor layer 7 and further to increase a grain size. Accordingly, the regularity of the crystal is improved, and the surface of the organic semiconductor layer 7 be planarized. As a result, it is possible to reduce the carrier mobility barrier in the channel area C of the interface between the organic semiconductor layer 7 and the gate insulating layer 9 and improve the mobility of the organic transistor 100.

### Second Embodiment

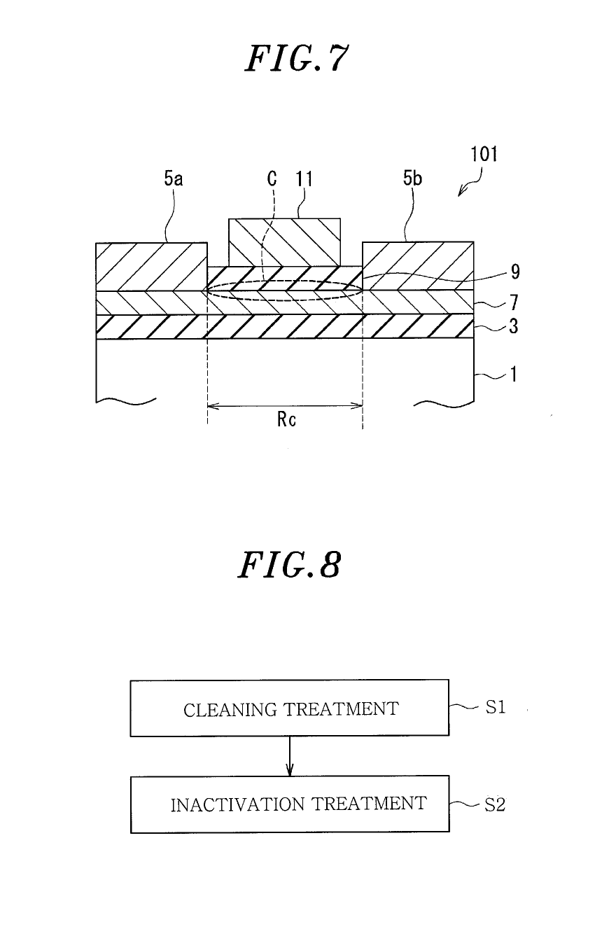

Hereinafter, a second embodiment of the present invention will be described with reference to FIG. 7. FIG. 7 is a view for explaining a schematic configuration of an organic transistor in accordance with a second embodiment of the present invention. This organic transistor 101 has a so-called top gate/top contact structure. In other words, the organic transistor 101 includes: a substrate 1 that is a supporting body; a base insulating layer 3 that is a first insulating layer formed on the substrate 1 with a predetermined thickness; an organic semiconductor layer 7 laminated to be in contact with the base insulating layer 3; a pair of source/drain electrodes 5a and 5b formed on a part of the organic semiconductor layer 7 in a predetermined pattern; a gate insulating layer 9 that is a second insulating layer laminated on the organic semiconductor layer 7 between the source electrode 5a and the drain electrode 5b; and a gate electrode 11 laminated on the gate insulating layer 9. The surface treatment is performed on the surface of the base insulating layer 3 which is in contact with the organic semiconductor layer 7 such that, the work of adhesion W1 in case where the organic semiconductor layer 7 is formed on the organic semiconductor layer, the work of adhesion W2 between the base insulating layer 3 and the organic semiconductor layer 7 in the case of forming the organic semiconductor layer 7 on the surface-treated base insulating layer 3 satisfies the relationship W1≧W2. The organic transistor 101 of the present embodiment has the same configuration as those of the organic transistor 100 of the first embodiment except that it has a top gate/top contact structure. Therefore, like reference numerals will be used for like parts, and redundant description will be omitted.

In the organic transistor 101 of the present embodiment as well, the surface treatment is performed on the base insulating layer 3 formed on the substrate 1. Due to the surface treatment, with respect to the work of adhesion W1 in the case where the organic semiconductor layer 7 is formed on the organic semiconductor layer, the work of adhesion W2 between the base insulating layer 3 and the organic semiconductor layer 7 in the case of forming the organic semiconductor layer 7 on the surface-treated base insulating layer 3 satisfies the relationship W1≧W2. By controlling the work of adhesion between the base insulating layer 3 and the organic semiconductor layer 7, the crystal growth of molecules forming the organic semiconductor layer 7 is facilitated and, further, a grain size is increased. Accordingly, the regularity of crystals is improved, and the surface of the organic semiconductor layer 7 can be planarized. As a result, it is possible to reduce the carrier mobility barrier in the channel area C of the interface between the organic semiconductor layer 7 and the gate insulating layer 9 and improve the mobility of the organic transistor 101.

The method for forming the organic transistor 101 of the present embodiment includes a step for laminating the base insulating layer 3 on the substrate 1; a step for laminating the organic semiconductor layer 7 to be in contact with the base insulating layer 3; a step for forming the source/drain electrodes 5a and 5b formed on a part of the organic semiconductor layer 7; a step for forming the gate insulating layer 9 on the organic semiconductor layer 7 between the source electrode 5a and the drain electrode 5b; and a step for forming the gate electrode 11 on the gate insulating layer 9. The method for manufacturing the organic transistor 101 of the present embodiment further includes a step for performing surface treatment on the surface of the base insulating layer 3 which is in contact with the organic semiconductor layer 7 such that, with respect to the work of adhesion W1 in the case where the organic semiconductor layer 7 is formed on the organic semiconductor layer, the work of adhesion W2 between the base insulating layer 3 and the organic semiconductor layer 7 in the case of forming the organic semiconductor layer 7 on the surface-treated base insulating layer 3 satisfies the relationship W1≧W2. Further, the method for manufacturing the organic transistor 101 of the present embodiment may include another step if necessary. The method for manufacturing the organic transistor 101 is the same as the method for manufacturing the organic transistor 100 of the first embodiment except that the organic semiconductor layer 7 is formed to be in contact with the base insulating layer and, then, the source/drain electrodes 5a and 5b are formed on the organic semiconductor layer 7.

In the present embodiment as well as the first modification of the first embodiment, the surface treatment can be performed on a part of the base insulating layer 3 which includes the area (channel corresponding area Rc) on the base insulating layer 3 corresponding to the channel area C formed in the boundary between the organic semiconductor layer 7 and the gate insulating layer 9. The other configurations and effects of the organic transistor 101 of the present embodiment are the same as those of the organic transistor 100 of the first embodiment.

### Third Embodiment

Hereinafter, a method for manufacturing an organic transistor (not shown) in accordance with a third embodiment of the present invention will be described with reference to FIG. 8. In the first and the second embodiment, the surface treatment step is performed by the first treatment (i) for inactivating the surface of the base insulating layer 3, the second treatment (ii) for reducing active species on the surface of the base insulating layer 3, or the third treatment (iii) for removing moisture from the surface of the base insulating layer 3, as described above. In the present embodiment, a cleaning treatment for cleaning the surface of the base insulating layer 3 is performed as the surface treatment step before the treatment such as the first treatment (i), the second treatment (ii) or the third treatment (iii) is performed. In other words, in the present embodiment, the surface treatment step includes the treatment such as the first treatment (i), the second treatment (ii) or the third treatment (iii) and the cleaning treatment performed before the treatment such as the first treatment (i), the second treatment (ii) or the third treatment (iii). By performing the cleaning treatment for cleaning the surface of the base insulating layer 3 as a part of the surface treatment, the surface state of the base insulating layer 3 can be made uniform, and the effects of the first treatment (i), the second treatment (ii) or the third treatment (iii) can be quantitatively recognized with ease.

FIG. 8 is a flowchart showing a sequence of the surface treatment step in the method for manufacturing the organic transistor of the present embodiment. Here, the case in which a-SrTiO₃ of the base insulating layer 3 is subjected to the inactivation treatment among the first to the third treatment (i) to (iii) will be described as an example. As in the first and the second embodiment, the base insulating layer 3 (and the source/drain electrodes 5a and 5b, if necessary) is formed and, then, the cleaning treatment S1 and the inactivation treatment S2 are performed in that order.

The cleaning treatment S1 of the base insulating layer 3 may be, e.g., radical treatment, combined treatment of UV treatment and annealing treatment, or the like.

The inactivation treatment S2 may be performed in the same manner as that of the first treatment (i) for inactivation in the first embodiment. Further, the second treatment (ii) or the third treatment (iii) may be performed instead of the inactivation treatment.

The other configurations and effects of the organic transistor of the present embodiment are the same as those of the organic transistors of the first and the second embodiment.

While the embodiments of the invention have been described in detail as examples, the present invention is not limited to the above embodiments.

The present international application claims priority based on Japanese Patent Application 2011-268827 filed on Dec. 8, 2011, the entire contents of which are incorporated herein by reference.

What is claimed is:

1. An organic transistor comprising:
a supporting body;
a first insulating layer laminated on the supporting body;
an organic semiconductor layer laminated on the first insulating layer;
a pair of source/drain electrodes partially in contact with the organic semiconductor layer;
a second insulating layer laminated on the organic semiconductor layer; and
a gate electrode formed on the second insulating layer,
wherein a surface of the first insulating layer which is in contact with the organic semiconductor layer has been subjected to a surface treatment by which, when W1 represents a work of adhesion between two laminated layers using the same material as a material of the organic semiconductor layer, a work of adhesion W2 between the first insulating layer and the organic semiconductor layer in the case of forming the organic semiconductor layer on the surface-treated first insulating layer satisfies relationship W1≧W2.

2. The organic transistor of claim 1, wherein at least a part of the surface of the first insulating layer, which corresponds to a channel area formed in the boundary between the organic semiconductor layer and the second insulating layer, has been subjected to the surface treatment.

3. The organic transistor of claim 1, wherein the surface treatment is a treatment for adhering a saturated hydrocarbon compound with 10 to 30 carbon atoms on the surface of the first insulating layer.

4. The organic transistor of claim 1, wherein the material of the organic semiconductor layer is pentacene.

5. The organic transistor of claim 1, wherein a material of the first insulating layer is SrTiO₃.

6. The organic transistor of claim 1, wherein the pair of source/drain electrodes has a top gate/bottom contact type structure provided below the organic semiconductor layer.

7. The organic transistor of claim 6, wherein a self-assembled monolayer film is formed on the pair of source/drain electrodes.

8. A method for manufacturing an organic transistor including a supporting body, a first insulating layer laminated on the supporting body, an organic semiconductor layer laminated on the first insulating layer, a pair of source/drain electrodes partially in contact with the organic semiconductor layer, a second insulating layer laminated on the organic semiconductor layer, and a gate electrode formed on the second insulating layer, the method comprising:
performing surface treatment on a surface of the first insulating layer which is to come in contact with the organic semiconductor layer; and
forming the organic semiconductor layer on the first insulating layer after the surface treatment,
wherein the surface treatment is performed such that, when W1 represents a work of adhesion between two laminated layers using the same material as a material used in the organic semiconductor layer, a work of adhesion W2 between the first insulating layer and the organic semiconductor layer in the case of forming the organic semiconductor layer on the surface-treated first insulating layer satisfies relationship W1≧W2.
